(19) United States
(12) Patent Application Publication
(10) Pub. No.: US 2025/0298059 A1
(43) Pub. Date: Sep. 25, 2025

(54) MEASURING SYSTEM FOR MEASURING CURRENT VALUES RELATING TO A CONDUCTOR AND FOR CORRECTING THE MEASURED CURRENT VALUES WITH REGARD TO CAPACITIVE INTERFERENCE INJECTION, AND METHOD FOR DETERMINING CALIBRATION COEFFICIENTS

(71) Applicant: Siemens Aktiengesellschaft, München (DE)

(72) Inventors: Roland Weiss, Erlangen (DE); Klaus Behringer, Igensdorf (DE); Franz Meierhöfer, Kirchensittenbach (DE); Daniel Pirstat, Amberg (DE); Stefan Hain, Effeltrich (DE)

(21) Appl. No.: 19/085,046

(22) Filed: Mar. 20, 2025

(30) Foreign Application Priority Data
Mar. 20, 2024 (DE) 10 2024 202 654.9

(51) Int. Cl. G01R 15/18; G01R 19/25; G01R 35/00

(52) U.S. Cl. CPC G01R 15/181; G01R 19/2506; G01R 35/005

(57) ABSTRACT

A measuring system for measuring current values pertaining to an alternating current flowing through a conductor and for correcting the measured current values regarding capacitive interference injection, includes a Rogowski coil configured inducing a voltage by way of alternating current, a signal processing device acquiring and processing values of the voltage induced in the Rogowski coil, a device determining a current value by integrating the voltage processed by the signal processing device, and a device correcting the current value regarding capacitive interference injection. The device correcting the current value is configured to make the correction by using an approximation

$$( {U}_{{ADC}_{{kap}_{1}}} ( t ) )$$

of a voltage drop caused by the capacitive interference injection. The correction improves measurement accuracy without additional hardware expenditure, permitting measuring instruments using Rogowski coils to be made smaller or more compact. A method for determining calibration coefficients is also provided.

### CROSS-REFERENCE TO RELATED APPLICATION

This application claims the priority, under 35 U.S.C. § 119, of German Patent Application DE 10 2024 202 654.9, filed Mar. 20, 2024; the prior application is herewith incorporated by reference in its entirety.

### FIELD AND BACKGROUND OF THE INVENTION

The invention relates to a measuring system formed by using a Rogowski coil for measuring current values relating to a conductor and for correcting the measured current values with regard to capacitive interference injection.

Rogowski coils are used for measuring alternating currents (AC current measurement). That involves the voltage at the output of the measuring winding of the Rogowski coils being used as a sensory variable. The voltage at the output of the measuring winding of the Rogowski coils is influenced not only by the time-varying magnetic field of the current to be measured (current in the current conductor to be measured (primary current)) but also by electric fields—and there especially by alternating electric fields. The main source for the alternating electric fields is the current conductor (primary current) itself, since it is based on mains potential (e.g. at a voltage of 230 Vrms and a frequency of 50 Hz; Vrms: root mean square value of the alternating voltage) with regard to the measuring circuit (see FIG. 1).

In general, the conductive winding of the Rogowski coil together with all conductive surfaces of the environment form a more or less complex capacitive structure. Due to the large distances—compared to discrete capacitors—between the winding of the Rogowski coil and the conductive surfaces (e.g. surface of the primary conductor), the corresponding coupling capacitances usually have only very low values. However, since the potential difference between those surfaces is very large—compared to the measured voltage at the ends of the Rogowski coil—even small coupling capacitances under normal operating conditions in low-voltage networks can lead to significant measurement errors when measuring the current using Rogowski coils.

Conventionally, that problem is solved by using shielding surfaces, e.g. made of expanded metal, by using an additional shielding winding made of thin wire or shielding material strips, or by shielding the entire sensor housing. If those shielding surfaces are held at the measuring potential of the coils by way of a suitable electrical connection to the measuring circuit, the shielding surfaces provide the necessary “opposite charges” on their surface for shielding the electric field. That means that the charge on the surface of the Rogowski coil does not have to be changed and no capacitive interference occurs at the measurement outputs of the Rogowski coil. Since good shielding must not affect the time-varying magnetic field in the Rogowski coil and at the same time should not significantly increase the space requirements of the Rogowski coil, the use of capacitive shields in small Rogowski coils is subject to certain limitations. When using shielding windings, it is important to note that both sides must not be connected to ground or reference-ground potential (to avoid circular currents).

In the past, larger Rogowski coils were often used to measure larger currents. For that purpose, Rogowski coils with a much larger diameter (diameter of the ring) but with a similar height of the ring were used. Generally, those larger Rogowski coils can be configured to provide a better signal-to-noise ratio. Put simply, e.g. increasing the distance between the winding of the Rogowski coils and the current conductor (primary current) leads to a reduction in the coupling capacitance. However, that is only possible if the installation space required is available in the electrical power distribution system. In general, alternating currents with an RMS value of less than 100 A in low-voltage applications can also be measured by using a toroidal core transformer. Besides some advantages over Rogowski coils, toroidal core transformers also have some disadvantages, such as higher costs, greater weight and a larger configuration or a significantly larger volume.

### SUMMARY OF THE INVENTION

It is accordingly an object of the invention to provide a measuring system for measuring current values relating to a conductor and for correcting the measured current values with regard to capacitive interference injection, and a method for determining calibration coefficients, which overcome the hereinafore-mentioned disadvantages of the heretofore-known systems and methods of this general type and which provide an efficient correction of interference injection in measuring systems based on Rogowski coils that do not require the space requirements of conventional systems to be increased.

With the foregoing and other objects in view there is provided, in accordance with the invention, a measuring system for measuring current values pertaining to an alternating current flowing through a conductor and for correcting the measured current values with regard to capacitive interference injection. This can also be a system having multiple phases, or conductors, and the capacitive interference injection from the other phases onto the conductor that is being examined can be considered. The measuring system can be a measuring device, e.g. power monitoring devices (PMD). However, the system may also be of multicomponent configuration, e.g. by virtue of measured values being transmitted to a central evaluation point, where they are corrected.

The inventive system includes a Rogowski coil, which is configured for inducing a voltage by way of alternating current. Typically, the monitored conductor is routed through the Rogowski coil. In addition, the system includes a signal processing unit for acquiring and processing values of the voltage induced in the Rogowski coil. This is formed e.g. using a circuit by way of which the induced voltage is tapped off, filtered and possibly amplified, in order to then be fed to an analog-to-digital converter. There may sometimes also be provision for post-processing for the digital signal. In addition, the system includes a device for determining a current value by integrating the voltage processed by the signal processing device, e.g. a microcontroller.

Preferably, the system is formed using an analog-to-digital converter and provides for digital integration of the processed voltage. However, the invention can, in principle, also be used for systems with analog integration that are based on a Rogowski coil. It is conceivable for analog systems to be supplemented by a (possibly external) device for correcting the current value that corrects the current values obtained by way of analog integration.

Advantageous developments are specified in the dependent claims.

According to the invention, a device for correcting the current value with regard to capacitive interference injection is additionally present, which is preferably identical to the device for determining a current value by way of integration. This device is configured, or programmed, to make the correction by using an approximation

$$( {U}_{{ADC}_{{kap}_{1}}} ( t ) )$$

of a voltage drop caused by the capacitive interference injection.

This approximation

$$( {U}_{{ADC}_{{kap}_{1}}} ( t ) )$$

is, for example, in a form in which it describes the voltage drop caused by the capacitive interference injection on the basis of at least one calibration coefficient (C_{K1.1}), the at least one calibration coefficient (C_{K1.1}) being determinable by way of one or more calibration measurements.

In addition, the approximation can contain at least one term that is proportional to the product of the calibration coefficient (C_{K1.1}), the derivative of a voltage

$$( \frac{d {U}_{μ} ( t )}{dt} )$$

attributable to the monitored conductor and a resistance (R_{i_RoGo}) attributable to the Rogowski coil. A plurality of phases can be considered and there may be provision for a corresponding term for each phase considered.

The approximation can be in the form

$$- \frac{1}{4} {\sum }_{μ} ( \frac{d {U}_{μ} ( t )}{dt} {C}_{K 1 , μ} ) \cdot {R}_{i \_ RoGo} ,$$

where the index μ runs through the phases considered, C_{K1,μ} is a calibration coefficient,

$$\frac{d {U}_{μ} ( t )}{dt}$$

is a derivative of a voltage attributable to the monitored conductor, and R_{i_RoGo} is a resistance (R_{i_RoGo}) attributable to the Rogowski coil.

The appearance of the correction by using the approximation

$$( {U}_{A D {C}_{k a {p}_{1}}} ( t ) )$$

of a voltage drop caused by the capacitive interference injection may be such that an expression obtained therefrom by way of integration (with arithmetic sign adjustment if applicable) is used in a formula for current values (I₁(t)) relating to the monitored conductor.

In general, the form of the approximation

$$( {U}_{A D {C}_{k a {p}_{1}}} ( t ) )$$

can be such that the integral thereof is a linear function term on the basis of a voltage (U_{μ}(t)) attributable to the conductor and, if applicable, of other phases considered for the approximation. This has the advantage that calibration measurements for determining coefficients result in a linear equation, or a linear system of equations, which is comparatively easy to solve.

The expression for current values (I₁(t)) relating to the conductor may be in the form

$${I}_{1} ( t ) = \frac{1}{4} {\sum }_{μ = 1}^{3} ( {U}_{μ} ( t ) {C}_{K 1 , μ} ) \cdot {R}_{{i}_{R o G o}} + \frac{1}{{M}_{11}} {\int }_{0}^{t} {U}_{A D {C}_{1} ( τ )} + {I}_{1} ( 0 ) ,$$

where the index μ runs through the phases considered, C_{K1,μ} is a calibration coefficient, U_{μ}(t) is a voltage attributable to a conductor (the conductor that is being checked or another phase that is being considered), R_{i_RoGo} is a resistance attributable to the Rogowski coil, and ∫₀^{t}U_{ADC}_{₁}_{(τ)} is the integral of a voltage induced in the Rogowski coil. The term “integral of a voltage induced in the Rogowski coil” should be understood to mean that these are voltage values that can be processed by using the signal processing device after induction in the Rogowski coil.

With the objects of the invention in view, there is also provided a method for determining calibration coefficients (C_{K1.1}) relating to an inventive measuring system by using calibration measurements. The starting point is an expression in the form:

$$\vec{I} ( t ) = ( \begin{matrix}{C}_{K 11} & {C}_{K 12} & {C}_{K 13} \\ {C}_{K 21} & {C}_{K 22} & {C}_{K 23} \\ {C}_{K 31} & {C}_{K 32} & {C}_{K 33}\end{matrix} ) * \vec{U} ( t ) + ( \begin{matrix}{S}_{11} & {S}_{12} & {S}_{13} \\ {S}_{21} & {S}_{22} & {S}_{23} \\ {S}_{31} & {S}_{32} & {S}_{33}\end{matrix} ) * {\int }_{0}^{t} {\vec{U}}_{A D C} ( τ ) + \vec{I} ( 0 ) ,$$

$$and$$

the calibration coefficients (C_{K1.1}) are determined by way of measurements when known currents are applied to the conductor and, if applicable, other phases. This includes the use of simplified expressions, e.g. by considering only one conductor or ignoring secondary diagonals of the matrices. The measurements are preferably taken when low voltages are applied to the conductor or the other phases (\vec{U}(t)).

The invention has the advantage that additional device elements necessary in conventional systems, which increase the space requirements, are not necessary. It is also possible to specify a mathematical expression through the use of which the correction can be made easily, efficiently and with little effort.

Other features which are considered as characteristic for the invention are set forth in the appended claims.

Although the invention is illustrated and described herein as embodied in a measuring system for measuring current values relating to a conductor and for correcting the measured current values with regard to capacitive interference injection, and a method for determining calibration coefficients, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a broadly outlined diagrammatic, perspective view of the formation of capacitive interference injection on the signal from Rogowski coils;

FIG. 2 is a schematic block diagram of a measuring device (power monitoring device) for acquiring measurement data related to a circuit;

FIG. 3 is a simple equivalent electrical circuit diagram for the combination of a Rogowski coil and an anti-aliasing low-pass filter;

FIG. 4 is a simplified equivalent electrical circuit diagram for the combination of a Rogowski coil and an anti-aliasing low-pass filter; and

FIG. 5 is a diagram showing a simulation result for capacitive coupling based on the equivalent circuit diagram from FIG. 3.

### DETAILED DESCRIPTION OF THE INVENTION

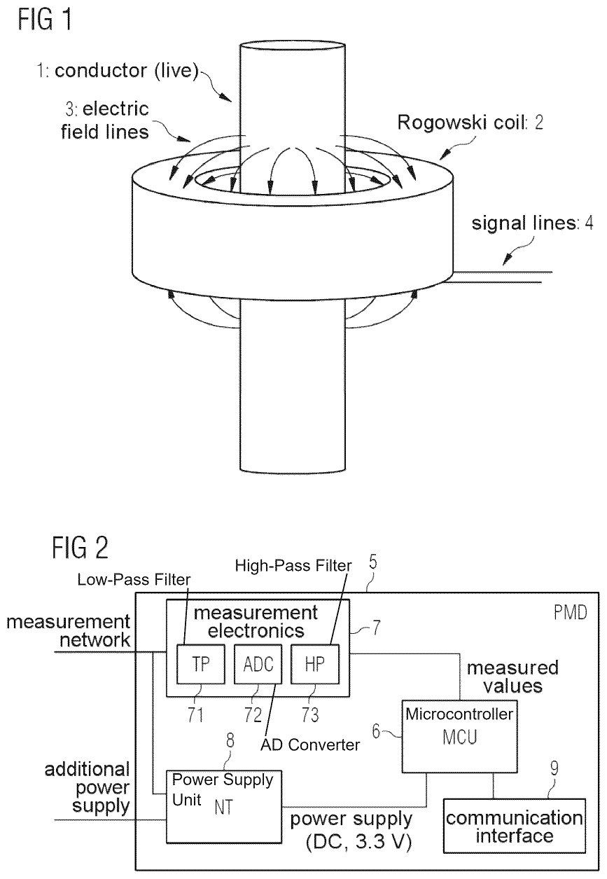

Referring now to the figures of the drawings in detail and first, particularly, to FIG. 1 thereof, there is seen a conductor 1 surrounded by a Rogowski coil 2. Electric field lines 3 are drawn to illustrate the effect of fields generated by the conductor 1 on the Rogowski coil 2, thereby affecting the voltage signal induced on signal lines 4 of the Rogowski coil 2.

More precisely, the alternating electric field that forms between the primary conductor 1 and the Rogowski coil 2 used for current measurement leads to potential fluctuations on the signal lines 4, or at the signal output of the Rogowski coil, relative to ground potential. Those potential fluctuations can lead to different interference during current measurement. That is referred to below as capacitive interference injection. That is a common term that derives from the fact that the surface of the conductor and the winding of the Rogowski coil form a capacitor. Besides an or the overdriving of the inputs of the measuring circuit, the capacitive interference injection leads above all to push-pull interference in the measuring circuit.

Power monitoring devices are often referred to as PMDs. Compact PMDs are used mainly to measure electrical power and thus to measure current and voltage at mains frequency.

FIG. 2 shows a PMD 5 for acquiring measurement data related to a circuit. This device may also be configured for determining consumption data.

Determination of consumption data may be configured e.g. for standardized billing for consumed energy (e.g. according to MID guideline EN 50470-1/3, or the standards IEC TR 63213 or IEC 61557-12).

The PMD 5 is connected to the circuit, or measurement network, to be monitored and receives measurement data that are acquired by a sensor (in this case by a Rogowski coil) and processed by measurement electronics 7. The measurement electronics usually include a low-pass filter 71 (anti-aliasing), an analog-to-digital converter, or ADC, 72 and a filter 73 for post-processing the digitized data, e.g. a high-pass filter. These components process the sensor data in the order in which they are listed above (see also German Patent DE 102015216981 B4 corresponding to U.S. Pat. No. 10,209,280 B2). The processed measurement data are processed further by a microcontroller, or an MCU, 6 (e.g. calculation of consumption data). The MCU 6 is additionally provided with an interface 9 that can be used to transmit or read data. In order to supply power to the MCU 6, there is provision for a power supply unit, or supply circuit, 8. This is supplied with power from the monitored circuit and delivers DC voltage at 3.3 V to the MCU 6. In order to safeguard the supply, PMDs usually have provision for an additional power supply for the supply circuit.

If Rogowski coils are used to measure current at mains frequency, these coils are often configured so that the internal impedance of the Rogowski coil is dominated by the nonreactive series resistance of the coil at mains frequency. At the same time, the impedance of the anti-aliasing filter 71 should be selected such that it is much higher than the nonreactive series resistance of the Rogowski coil. In order to avoid adverse influences on the quality of the signal from the Rogowski coil, e.g. due to temperature drift, the value of the “resistive component” of the anti-aliasing low-pass filter is generally selected to be much higher than the value of the nonreactive series resistance of the Rogowski coil (RAA>Ri_Rogo→1/(ωmess*C)>RAA>Ri_Rogo)) (see eq. 1). The capacitance CK of the capacitive coupling and the values RAA and CAA of the anti-aliasing low-pass filter result in the following relationship:

$$\frac{1}{2 π f \cdot {C}_{k}} ≫ \frac{1}{2 π f \cdot {C}_{A A}} ≫ {R}_{A A} > {R}_{i \_ Rogo} \qquad eq . 1$$

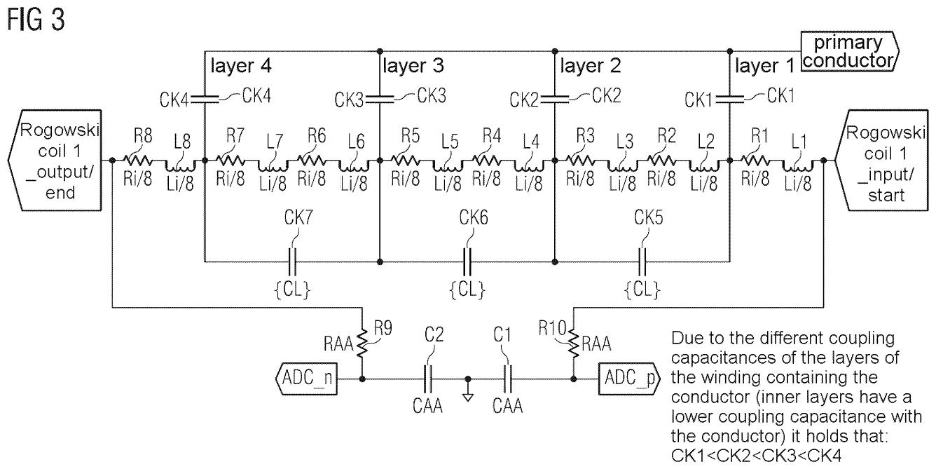

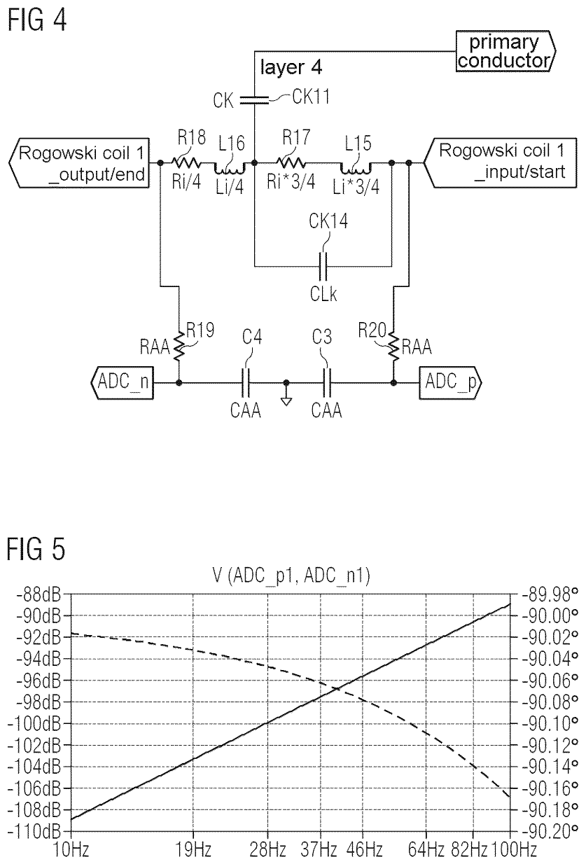

If the value of the impedance of the capacitive coupling between the primary conductor and the Rogowski coil in the range of the measurement frequencies (PMDs, or power monitoring devices, measure primarily at mains frequency) is much greater than the value of the nonreactive series resistance of the Rogowski coil, the equivalent circuit diagram from FIG. 3 can be simplified considerably. This greatly simplified equivalent circuit diagram is shown in FIG. 4.

With the equivalent circuit diagram from FIG. 4 and the approximation from eq. 1, the following approximation formula can be specified for the current through the coupling capacitance:

$$ICK = U \cdot j ω CK \qquad eq . 2$$

The underscore indicates that these are complex variables.

Thus, the capacitive couplings between the conductor 1 and the Rogowski coil 2 lead to approximately the following voltage drop across the analog-to-digital converter (ADC) 72:

$${\underline{U}}_{ADC} = {\underline{U}}_{ADC \_ p} - {\underline{U}}_{ADC \_ n} = - \frac{1}{4} \underline{U} \cdot j ω {C}_{K} \cdot {R}_{i \_ RoGo} \qquad eq . 3$$

where Ri_RoGo is the value of the nonreactive series resistance of the Rogowski coil. The frequency response of the simulation result shown in FIG. 5 clearly confirms the relationship from eq. 3.

The relationship from eq. 3 can be extended to include the influence of all phases of the distribution system (since they are often also in direct proximity to one another):

$${\underline{U}}_{ADC \_ 1} = {\underline{U}}_{ADC \_ p \_ 1} - {\underline{U}}_{ADC \_ {n}_{1}} = - \frac{1}{4} {\sum }_{μ = 1}^{3} ( {\underline{U}}_{μ} \cdot j ω {C}_{K 1 , μ} ) \cdot {R}_{i \_ RoGo} \qquad eq . 4$$

This results in the following relationship for the voltage at the input of the measuring system, or the analog-to-digital converter (ADC), for the time domain:

$${U}_{A D {C}_{k a {p}_{1}}} ( t ) = - \frac{1}{4} {\sum }_{μ = 1}^{3} ( \frac{d {U}_{μ} ( t )}{dt} {C}_{K 1 , μ} ) \cdot {R}_{i \_ RoGo} \qquad eq . 5$$

$$where :$$

$${C}_{K 1.1} ≫ {C}_{K 1.2} {C}_{K 1.1} ≫ {C}_{K 1.3} \qquad eq . 6$$

For the total voltage at the output of the combination of a Rogowski coil 2 and an anti-aliasing low-pass filter 71, and thus at the input of the analog-to-digital converter (ADC) 72, equation eq. 7 follows.

$${U}_{A D {C}_{1}} ( t ) = {U}_{A D {C}_{k a {p}_{1}}} ( t ) + {U}_{R o G {o}_{1}} ( t ) = - \frac{1}{4} \cdot {R}_{{i}_{R o G o}} \cdot {\sum }_{μ = 1}^{3} \frac{d {U}_{μ} ( t )}{dt} {C}_{K 1 , μ} + {M}_{11} \cdot \frac{{dI}_{1} ( t )}{dt} \qquad eq . 7$$

In order to analyze the current to be measured by the Rogowski coil 2, the output signal from the Rogowski coil 2 is in most cases subjected to analog or digital integration. The usefulness of integrating the output signal from the Rogowski coil 2, or the input signal for the analog-to-digital converter ADC 72, can be ascertained directly from eq. 7. This integration yields the following relationship for the current, provided that inductive interference injection can be ignored:

$${I}_{1} ( t ) = \frac{1}{4} {\sum }_{μ = 1}^{3} ( {U}_{μ} ( t ) {C}_{K 1 , μ} ) \cdot {R}_{{i}_{R o G o}} + \frac{1}{{M}_{11}} {\int }_{0}^{t} {U}_{A D {C}_{1} ( τ )} + {I}_{1} ( 0 ) \qquad eq . 8$$

As is evident from eq. 7 and eq. 8, correcting the capacitive interference injection requires the values of the voltages on the conductors that are in the direct surroundings of the Rogowski coil 1 in a polyphase system to be known (below, a three-phase system is assumed for the equations, i.e. e.g. three conductors, each of which—as shown for one conductor in FIG. 1—may be surrounded by a Rogowski coil). Since the values of the coupling capacitances from e.g. phase 2 to coil 1 are, due to geometry, very often much lower than the values of the coupling capacitances from e.g. phase 1 to coil 1, these couplings can then be ignored. Since the values of the capacitances CK1,μ are sometimes dependent on manufacturing tolerances, it is advisable to determine the values of the coefficients for the digital correction as part of a calibration, and here above all when calibrating the voltage measurement of the PMD. During operation of the PMD, the results of the voltage measurement and the calibration coefficients cK1,μ stored in the measuring system are then used to correct the current values obtained from the integration of the output voltage of the Rogowski coil. In order to facilitate clear attribution of the individual effects, the calibration coefficients cK1,μ should be determined at preferably zero current (when calibrating the measuring channels for voltage measurement, only very small currents, measured against the rated current, should flow). Accordingly, only very low voltages should be used for calibrating the measuring channels for current measurement.

$$\vec{I} ( t ) = ( \begin{matrix}{c}_{K 11} & {c}_{K 12} & {c}_{K 13} \\ {c}_{K 21} & {c}_{K 22} & {c}_{K 23} \\ {c}_{K 31} & {c}_{K 32} & {c}_{K 33}\end{matrix} ) * \vec{U} ( t ) + ( \begin{matrix}{S}_{11} & {S}_{12} & {S}_{13} \\ {S}_{21} & {S}_{22} & {S}_{23} \\ {S}_{31} & {S}_{32} & {S}_{33}\end{matrix} ) * {\int }_{0}^{t} {\vec{U}}_{ADC} ( τ ) + \vec{I} ( 0 ) \qquad eq . 9$$

Here the multiplication is indicated by “*” to make it clear that this is an operation with matrices. \vec{U}(t) is the vector of the voltages of the individual phases.

It is also important to note here that the values of the secondary diagonal elements in both the matrix CK and the matrix S are often much smaller than the main diagonal elements and can therefore be ignored. This greatly simplifies calculation of the correction of the capacitive coupling and allows it to be performed well on a microcontroller 6 or on comparable embedded hardware.

The determination of the coupling coefficients is illustrated below on the basis of the simplest case, namely a single conductor. Eq. 9 is then reduced to:

$$I ( t ) = {c}_{K} \cdot U ( t ) + S \cdot {\int }_{0}^{t} {U}_{ADC} ( τ ) + I ( 0 ) . \qquad eq . 10$$

A predetermined, generated test current I(t) is applied. The voltage U(t) on the conductor is measured or is also known. The microcontroller 6 integrates the voltage U_{ADC} induced in the Rogowski coil and processed, as a result of which ∫₀^{t}U_{ADC}(τ) is obtained for times t. Determining the two coefficients C_{K} and S requires two equations. For this purpose, the variables of eq. 10 can be determined for different times t1 and t2, or different test currents I(t) can also be used for the operation.

The inventive correction achieves an improvement of the measurement accuracy without additional hardware expenditure. Measuring instruments formed by using Rogowski coils can thus be made smaller or more compact.

1. A measuring system for measuring current values pertaining to an alternating current flowing through a conductor and for correcting the measured current values with regard to capacitive interference injection, the measuring system comprising:
a Rogowski coil configured for inducing a voltage by way of alternating current;
a signal processing device for acquiring and processing values of the voltage induced in said Rogowski coil;
a device for determining a current value by integrating the voltage processed by said signal processing device; and
a device for correcting the current value with regard to capacitive interference injection, said device for correcting the current value being configured to make the correction by using an approximation
$$( {U}_{A D {C}_{k a {p}_{1}}} ( t ) )$$
of a voltage drop caused by the capacitive interference injection.

2. The measuring system according to claim 1, wherein the approximation
$$( {U}_{A D {C}_{k a {p}_{1}}} ( t ) )$$
describes the voltage drop caused by the capacitive interference injection based on at least one calibration coefficient (C_{K1.1}), the at least one calibration coefficient (C_{K1.1}) being determinable by using calibration measurement.

3. The measuring system according to claim 2, wherein the approximation contains at least one term being proportional to a product of the calibration coefficient (C_{K1.1}), a derivative of a voltaged
$$( \frac{{dU}_{μ} ( t )}{dt} )$$
attributable to the conductor and a resistance (R_{i_RoGo}) attributable to said Rogowski coil.

4. The measuring system according to claim 3, wherein a plurality of phases are considered and a term is provided for each phase being considered.

5. The measuring system according to claim 4, wherein the approximation is in a form
$$- \frac{1}{4} {\sum }_{μ} ( \frac{{dU}_{μ} ( t )}{dt} {C}_{K 1 , μ} ) \cdot {R}_{i \_ RoGo} ,$$
where an index μ runs through the phases being considered, C_{K1,μ} is the calibration coefficient,
$$\frac{{dU}_{μ} ( t )}{dt}$$
is a derivative of a voltage
$$( \frac{{dU}_{μ} ( t )}{dt} )$$
attributable to the conductor and a resistance (R_{i_RoGo}) attributable to said Rogowski coil.

6. The measuring system according to claim 1, wherein the correction is made by using the approximation
$$( {U}_{{ADC}_{{kap}_{1}}} ( t ) )$$
of a voltage drop caused by the capacitive interference injection in such a way that the expression for current values (I₁(t)) relating to the conductor is used containing an integral of the approximation.

7. The measuring system according to claim 6, wherein the form of the approximation
$$( {U}_{{ADC}_{{kap}_{1}}} ( t ) )$$
is such that the integral thereof is a linear function term based on a voltage (U_{μ}(t)) attributable to the conductor.

8. The measuring system according to claim 6, wherein the form of the approximation
$$( {U}_{{ADC}_{{kap}_{1}}} ( t ) )$$
is such that the integral thereof is a linear function term based on a voltage (U_{μ}(t)) attributable to the conductor and of other phases considered for the approximation.

9. The measuring system according to claim 7, wherein the expression for current values (I₁(t)) relating to the conductor is in a form
$${I}_{1} ( t ) = \frac{1}{4} {\sum }_{μ = 1}^{3} ( {U}_{μ} ( t ) {C}_{K 1 , μ} ) \cdot {R}_{{i}_{RoGo}} \cdot + \frac{1}{{M}_{11}} {\int }_{0}^{t} {U}_{{ADC}_{1} ( τ )} + {I}_{1} ( 0 ) ,$$
where an index μ runs through phases being considered, C_{K1,μ} is the calibration coefficient, U_{μ}(t) is a voltage attributable to the conductor, R_{i_RoGo} is a resistance attributable to said Rogowski coil, and ∫₀^{t}U_{ADC}_{₁}_{(τ)} is an integral of a voltage induced in said Rogowski coil.

10. The measuring system according to claim 8, wherein the expression for current values (I₁(t)) relating to the conductor is in a form
$${I}_{1} ( t ) = \frac{1}{4} {\sum }_{μ = 1}^{3} ( {U}_{μ} ( t ) {C}_{K 1 , μ} ) \cdot {R}_{{i}_{RoGo}} \cdot + \frac{1}{{M}_{11}} {\int }_{0}^{t} {U}_{{ADC}_{1} ( τ )} + {I}_{1} ( 0 ) ,$$
where an index μ runs through phases being considered, C_{K1,μ} is a calibration coefficient, U_{μ}(t) is a voltage attributable to the conductor, R_{i_RoGo} is a resistance attributable to said Rogowski coil, and ∫₀^{t}U_{ADC}_{₁}_{(τ)} is an integral of a voltage induced in said Rogowski coil.

11. A method for determining calibration coefficients (C_{K1.1}) relating to a measuring system according to claim 2, the method comprising:
providing a starting point being an expression in a form:
$$\vec{I} ( t ) = ( \begin{matrix}{c}_{K 11} & {c}_{K 12} & {c}_{K 13} \\ {c}_{K 21} & {c}_{K 22} & {c}_{K 23} \\ {c}_{K 31} & {c}_{K 32} & {c}_{K 33}\end{matrix} ) * \vec{U} ( t ) + ( \begin{matrix}{S}_{11} & {S}_{12} & {S}_{13} \\ {S}_{21} & {S}_{22} & {S}_{23} \\ {S}_{31} & {S}_{32} & {S}_{33}\end{matrix} ) * {\int }_{0}^{t} {\vec{U}}_{ADC} ( τ ) + \vec{I} ( 0 ) ,$$
and
determining the calibration coefficients (C_{K1.1}) by way of measurements upon applying known currents to the conductor.

12. The method according to claim 11, which further comprises determining the calibration coefficients by way of the measurements upon applying the known currents to the conductor and other phases.

13. The method according to claim 12, which further comprises taking the measurements when low voltages are applied to the conductor or the other phases (\vec{U}(t)).
